(19) United States
(12) Patent Application Publication
(10) Pub. No.: US 2015/0263144 A1
(43) Pub. Date: Sep. 17, 2015

(54) SEMICONDUCTOR DEVICE AND INSULATED GATE BIPOLAR TRANSISTOR

(71) Applicant: KABUSHIKI KAISHA TOSHIBA, Tokyo (JP)

(72) Inventors: Shinichiro MISU, Machida Tokyo (JP); Tsuneo OGURA, Kamakura Kanagawa (JP)

(21) Appl. No.: 14/475,501

(22) Filed: Sep. 2, 2014

(30) Foreign Application Priority Data
Mar. 13, 2014 (JP) 2014-050813

(51) Int. Cl. H01L 29/739; H01L 29/10; H01L 29/36

(52) U.S. Cl. CPC H01L 29/7393; H01L 29/36; H01L 29/1095

(57) ABSTRACT

According to one embodiment, an insulated gate bipolar transistor includes a main region, a sense region, and a semiconductor layer that is provided between the main region and the sense region, is in contact with a collector layer of a first conductivity type provided in the main region and the sense region, and has one of a dopant concentration lower than a dopant concentration of the collector layer or a second conductivity type opposite the first conductivity type.

### CROSS-REFERENCE TO RELATED APPLICATION

This application is based upon and claims the benefit of priority from Japanese Patent Application No. 2014-050813, filed Mar. 13, 2014, the entire contents of which are incorporated herein by reference.

### FIELD

Embodiments described herein relate generally to a semiconductor device and an insulated gate bipolar transistor.

### BACKGROUND

A semiconductor device such as an insulated gate bipolar transistor (IGBT) has a possibility of being damaged when a high current flows therethrough. Therefore, in order to detect a high current flow and protect the semiconductor device from the damage, it is preferable that the current flowing through the semiconductor device be monitored. Therefore, a configuration is known in which a sense region through which a sense current flows is provided independently of a main region through which a main current flows. When the main current is proportional to the sense current, the main current may be estimated by measuring the sense current.

However, when isolation between the main region and the sense region is insufficient, the main current is not necessarily proportional to the sense current by a fixed or known amount. As a result, there is a problem in that it is hard to accurately determine the level of the flowing main current.

### DESCRIPTION OF THE DRAWINGS

FIG. 1 is a circuit diagram of a semiconductor device according to a first embodiment.

FIG. 2 is a cross-sectional view illustrating the semiconductor device according to the first embodiment.

FIGS. 3A and 3B are diagrams schematically illustrating a current flow in the semiconductor device.

FIG. 4 is a graph illustrating a calculation example of a relationship between a sense ratio Im/Is and a main current Im.

FIG. 5 is a cross-sectional view illustrating a semiconductor device which is a first modification example of the semiconductor device.

FIG. 6 is a cross-sectional view illustrating a semiconductor device which is a second modification example of the semiconductor device.

FIG. 7 is a cross-sectional view illustrating a semiconductor device which is a third modification example of the semiconductor device.

FIG. 8 is a cross-sectional view illustrating a semiconductor device which is a fourth modification example of the semiconductor device.

FIG. 9 is a cross-sectional view illustrating a semiconductor device according to a second embodiment.

FIG. 10 is a cross-sectional view of a semiconductor device according to a third embodiment.

FIG. 11 is a cross-sectional view of a semiconductor device according to a fourth embodiment.

### DETAILED DESCRIPTION

A semiconductor device and an insulated gate bipolar transistor which are capable of accurately detecting a current amount are provided in an embodiment of the present disclosure.

In an embodiment, an insulated gate bipolar transistor comprises a main region and a sense region spaced from the main region. A first semiconductor layer is disposed between the main region and the sense region. The first semiconductor layer is in contact with a first portion of a collector layer of a first conductivity type in the main region and a second portion of the collector layer in the sense region. The first semiconductor layer is one of a layer of the first conductivity type with a first conductivity type dopant concentration that is lower than a first conductivity type dopant concentration of the collector layer or a layer of a second conductivity type that is opposite the first conductivity type.

In general, according to one embodiment, there is provided an insulated gate bipolar transistor including: a main region; a sense region; and a semiconductor layer that is provided between the main region and the sense region, is in contact with a collector layer provided in the main region and the sense region, and has a dopant concentration lower than a dopant concentration of the collector layer.

Hereinafter, the embodiments will be described in detail with reference to the accompanying drawings.

### First Embodiment

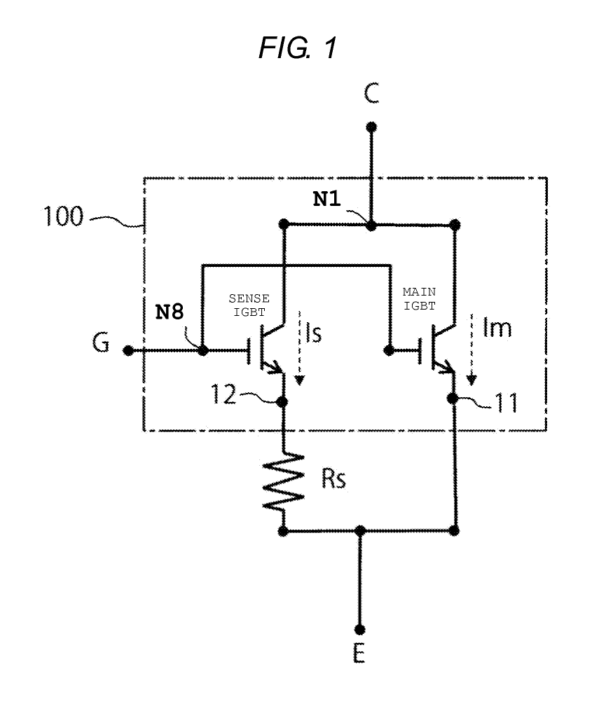

FIG. 1 is an equivalent circuit diagram of a semiconductor device 100 according to a first embodiment. The semiconductor device 100 includes a main IGBT that is formed in a main region and a sense IGBT that is formed in a sense region. In addition, an isolation region (not specifically depicted in FIG. 1) is provided between the main region and the sense region.

Collector electrodes of the main IGBT and the sense IGBT are connected to each other at node N1. Likewise, gate electrodes of the main IGBT and the sense IGBT are connected to each other at node N8. On the other hand, an emitter electrode 12 of the sense IGBT is electrically separated from an emitter electrode 11 of the main IGBT in the semiconductor device 100. A total emitter potential E of the IGBT is directly supplied to the emitter electrode 11 of the main IGBT, and is supplied through a sense resistor Rs to the emitter electrode 12 of the sense IGBT.

A main current Im flows through the main region. A sense current Is corresponding to the main current Im flows through the sense region. The sense current Is may be estimated from a voltage drop in the sense resistor Rs.

When the main current Im is proportional to the sense current Is, the main current Im may be accurately determined from the sense current Is. However, if isolation between the main region and the sense region, which are nominally separated by an isolation region, is insufficient, a current flows from the main region and the sense regions to the isolation region. As a result, the sense current Is is not proportional to the main current Im. Therefore, it is hard to accurately determine the main current Im flowing through the semiconductor device 100 based only on the sense current Is.

In the first embodiment, a current flow to the isolation region may be suppressed, and the isolation between the main region and the sense region may be improved.

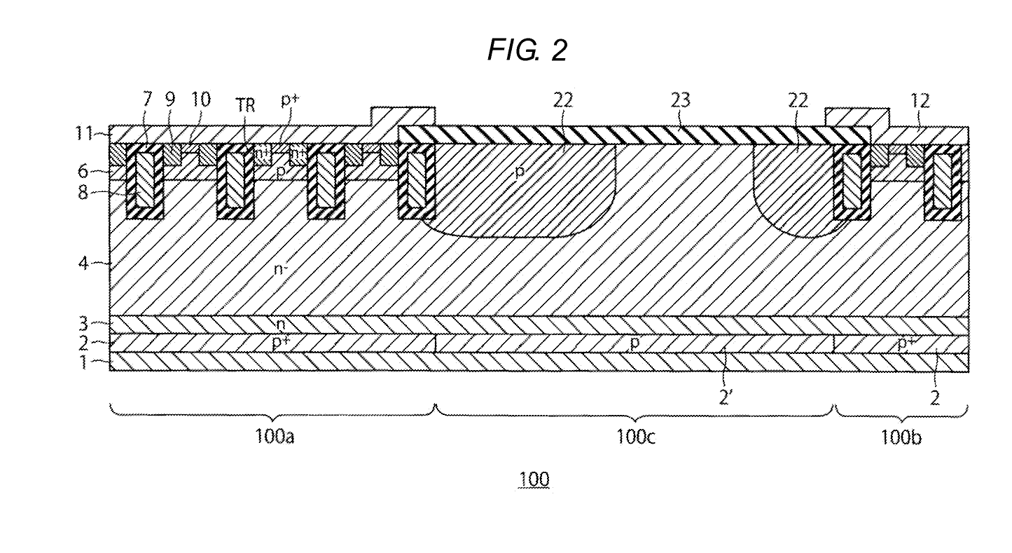

FIG. 2 is a cross-sectional view illustrating the semiconductor device 100 according to the first embodiment. The semiconductor device 100 includes a main region (first region) 100a, a sense region (second region) 100b, and an isolation region (third region) 100c. The main region 100a is provided distant from the sense region 100b. The isolation region 100c is provided between the main region 100a and the sense region 100b such that the main region 100a and the sense region 100b are separated from each other by the isolation region 100c.

First, the main region 100a of the semiconductor device 100 will be described. IGBT elements formed of plural base units are provided in the main region 100a. The main region 100a includes a collector electrode (first electrode) 1, p⁺ type (first conductivity type) semiconductor layers (first semiconductor layer) 2, an n type (second conductivity type) semiconductor layer 3, an n⁻ type semiconductor layer (second semiconductor layer) 4, a p type semiconductor layer (third semiconductor layer) 6, gate insulating films (insulating films) 7, gate electrodes (second electrodes) 8, n⁺ type semiconductor layers (fourth semiconductor layers) 9, p⁺ type semiconductor layers 10, and an emitter electrode (third electrode) 11.

The p⁺ type semiconductor layers 2 are a collector layers that are provided on the collector electrode 1, which is formed of aluminum or the like. The n type semiconductor layer 3 is a buffer layer that is provided on the p⁺ type semiconductor layers 2. The n type semiconductor layer 3 is not necessarily provided, but it is preferably provided to improve performance during operation of the IGBT. The n⁻ type semiconductor layer 4 is a base layer that is provided on the semiconductor layer 3. The n⁻ type semiconductor layer 4 may be a semiconductor substrate formed of silicon or the like. The p type semiconductor layer 6 is a base layer that is provided on the n⁻ type semiconductor layer 4.

Plural trenches TR that penetrate the p type semiconductor layer 6 and reach the n⁻ type semiconductor layer 4 are formed at intervals. Gate insulating films 7, comprising material such as a silicon oxide film, are provided inside these trenches TR. That is, the gate insulating films 7 are provided on the n⁻ type semiconductor layer 4 at intervals. The p type semiconductor layer 6 is provided on the n⁻ type semiconductor layer 4 between the plural gate insulating films 7.

The gate electrodes 8 are provided on the gate insulating films 7 in the trenches TR. In other words, the gate electrodes 8 are provided on the n⁻ type semiconductor layer 4 via the insulating films 7. Accordingly, the side surfaces of the gate electrodes 8 face the p type semiconductor layer 6 through the gate insulating films 7. The bottoms of the gate electrodes 8 face the n⁻ type semiconductor layer 4 through the gate insulating films 7. The gate insulating films 7 are also provided on the gate electrodes 8—that is, above the gate electrodes 8 in the trenches TR.

The n⁺ type semiconductor layers 9 are emitter layers are provided on the p type semiconductor layer 6 and in contact with the gate insulating films 7. That is, the n⁺ type semiconductor layers 9 are provided on the p type semiconductor layer 6 to be in contact with the insulating films 7. The n+ type semiconductor layers 9 are provided on some portions of the p type semiconductor layer 6 and not other portions. The p⁺ type semiconductor layers 10 are contact layers provided on the p type semiconductor layer 6 and between the n⁺ type semiconductor layers 9. The p⁺ type semiconductor layers 10 are not necessarily required for operation of the IGBT but are preferably provided to reduce a contact resistance between the p type semiconductor layer 6 and the emitter electrode 11. The emitter electrode 11 is formed of aluminum or the like and is provided on the gate insulating films 7, the n⁺ type semiconductor layers 9, and the p⁺ type semiconductor layers 10. In other words, the emitter electrode 11 is provided in contact with the insulating films 7 and the n⁺ type semiconductor layers 9. In addition, an insulator layer 23 (described more fully below) extends from the isolation region 100c to gate insulating films 7, and a portion of the emitter electrode 11 is provided on the insulator layer 23. The gate electrodes 8 and the emitter electrode 11 are insulated from each other by at least the gate insulating film 7.

Next, the sense region 100b of the semiconductor device 100 will be described. The sense region 100b is provided at a position separated, preferably distant, from the main region 100a. IGBT elements formed of plural base units are also provided in the sense region 100b. However, the area of the sense region 100b is smaller than that of the main region 100a. In addition, the number of IGBT elements provided in the sense region 100b is less than the number of IGBT elements provided in the main region 100a. Accordingly, the sense current Is is less than the main current Im.

A device structure of the sense region 100b is substantially the same as that of the main region 100a. However, the emitter electrode (fourth electrode) 12 in the sense region 100b is not connected to the emitter electrode 11 in the main region 100a. Accordingly, the potential of the emitter electrode 12 is not necessarily the same as that of the emitter electrode 11. During the operation, the potentials of electrode 11 and electrode 12 may be different from each other, as described below.

Next, the isolation region 100c of the semiconductor device 100 will be described. The isolation region 100c includes the collector electrode 1, a p type semiconductor layer 2′, the n type semiconductor layer 3, the n⁻ type semiconductor layer 4, p type semiconductor layers 22, and the insulator layer 23.

The collector electrode 1, the n type semiconductor layer 3, and the n⁻ type semiconductor layer 4 are common to those in the main region 100a and the sense region 100b. The p type semiconductor layers 22 are provided at a position in contact with the main region 100a and a position in contact with the sense region 100b on the n⁻ type semiconductor layer 4. The p type semiconductor layers 22 cover a corner of the bottom of the trench TR in the main region 100a and the sense region 100b nearest the isolation region 100c which are positioned closest to the isolation region 100c, of the main region 100a and the sense region 100b. In other words, the p type semiconductor layer 22 adjacent to the respective main region 100a and the sense region 100b extends below the bottoms of insulating films 7 in the trenches TR and into the respective main region 100a or the sense region 100b. By providing the p type semiconductor layers 22, a breakdown voltage between the emitter electrodes 11 and 12 and the collector electrode 1 may be improved. When there are no p type semiconductor layers 22, an electric field is concentrated at corners of trenches of the main region 100a and the sense region 100b on the isolation region 100c side of the IGBT, and thus the breakdown voltage is lower. The specific structure for improving the breakdown of this first embodiment is exemplary, and the breakdown voltage may also be achieved using another method.

The insulating layer 23 such as a silicon oxide layer is provided on the p type semiconductor layers 22 and the n⁻ type semiconductor layer 4. The insulating layer 23 extends to the insulating films 7, which are positioned on the isolation region 100c side, of the main region 100a and the sense region 100b.

Similarly to the p⁺ type semiconductor layers 2 in the main region 100a and the sense region 100b, the p type semiconductor layer 2′ is provided between the collector electrode 1 and the n type semiconductor layer 3. However, as one characteristic of the first embodiment, the dopant concentration of the p type semiconductor layer 2′ in the isolation region 100c is lower than those of the p⁺ type semiconductor layers 2 in the main region 100a and the sense region 100b. Specifically, the maximum value of the dopant concentration of the p type semiconductor layer 2′ in the isolation region 100c is approximately 10¹⁶/cm³. On the other hand, the maximum value of the dopant concentrations of the p⁺ type semiconductor layers 2 in the main region 100a and the sense region 100b is approximately 10¹⁸/cm³. The dopant concentration of the p⁺ type semiconductor layer 2 in the main region 100a may be different from that of the p⁺ type semiconductor layer 2 in the sense region 100b.

Next, the operation of the semiconductor layer 100 will be described.

In the main region 100a and the sense region 100b, when a positive voltage is applied to the gate electrodes 8 in the main region 100a and the sense region 100b, n type channels are formed at interfaces between the p type semiconductor layer 6 and the gate insulating films 7. In this state, when the potential of the collector electrode 1 is higher than that of the emitter electrode 11, electrons are injected from the emitter electrode 11 to the n⁻ type semiconductor layer 4 through the n⁺ type semiconductor layers 9 and the n type channels. These electrons pass through the n type semiconductor layer 3 and the p⁺ type semiconductor layers 2 and reach the collector electrode 1. Holes are injected from the p⁺ type semiconductor layers 2 to the n⁻ type semiconductor layer 4 through the n type semiconductor layer 3. These holes pass through the p type semiconductor layer 6 and the p⁺ type semiconductor layers 10 and reach the emitter electrode 11.

In this way, in the main region 100a and the sense region 100b, electrons are moved from the emitter electrodes 11 and 12 to the collector electrode 1, and holes are moved from the collector electrode 1 to the emitter electrodes 11 and 12. As a result, the main current Im and the sense current Is current flow from the collector electrode 1 toward the emitter electrodes 11 and 12, respectively.

On the other hand, since the insulator layer 23 is provided in the isolation region 100c, substantially no current flows in this region.

Next, an effect obtained by providing the p type semiconductor layer 2′ in the isolation region will be described.

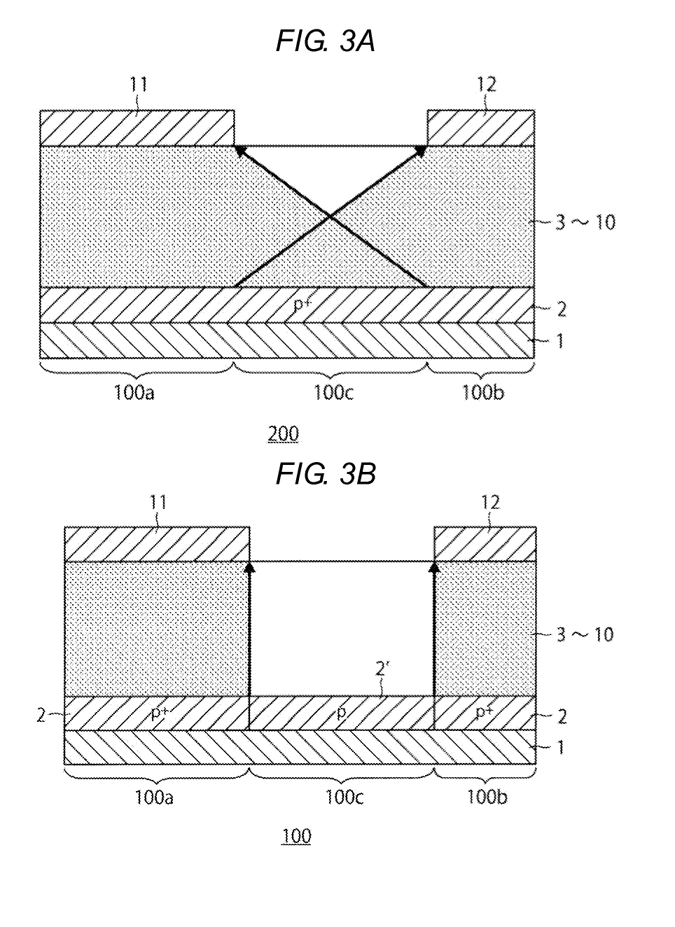

FIGS. 3A and 3B are diagrams schematically illustrating a current flow of the semiconductor device 100. For reference, FIG. 3A illustrates a current flow of a semiconductor device 200 obtained by providing only the p⁺ type semiconductor layer 2 instead of including the p type semiconductor layer 2′ in the isolation region 100c in the semiconductor device 100. In addition, FIG. 3B illustrates a current flow of the semiconductor device 100. In FIGS. 3A and 3B, the semiconductor devices 100 and 200 are simplified and certain elements (e.g., gate electrodes 8) are omitted for simplicity.

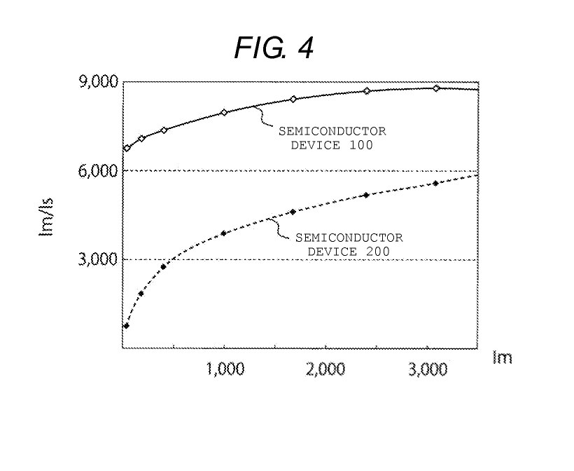

In addition, FIG. 4 is a graph illustrating a calculation example of a relationship between a sense ratio Im/Is and the main current Im. The horizontal axis represents the main current Im, and the vertical axis represents the sense ratio Im/Is. In this case, the main current Im and the sense current Is flow through the main IGBT and the sense IGBT of FIG. 1, respectively. The sense current Is flowing through the sense IGBT is measured based a potential difference between both ends of the sense resistor Rs of FIG. 1. In FIG. 4, the solid line represents the characteristics of the semiconductor device 100, and the broken line represents the characteristics of the semiconductor device 200.

As illustrated in FIG. 3A, in the case of the semiconductor device 200, the p⁺ type semiconductor layer 2 is also provided in the isolation region 100c. Therefore, holes injected from the p⁺ type semiconductor layer 2 of the isolation region 100c may reach the emitter electrode 11 of the main region 100a and the emitter electrode 12 of the sense region 100b. That is, holes injected from the p⁺ type semiconductor layer 2 of the isolation region 100c close to the main region 100a may reach the emitter electrode 12 of the sense region 100b. Likewise, holes injected from the p⁺ type semiconductor layer 2 of the isolation region 100c close to the sense region 100b may reach the emitter electrode 11 of the main region 100a.

As a result, a current flows through a highlighted region of FIG. 3A, and a current flowing through the main region 100a and a current flowing through the sense region 100b cannot be separated from each other. Accordingly, as indicated by the broken line of FIG. 4, the sense ratio is not constant. Therefore, an accurate current value cannot be detected, and there may be a problem that, for example, the semiconductor device 200 cannot be sufficiently protected from overcurrent, a malfunction occurs, or it is necessary that a large operating margin be provided.

On the other hand, as illustrated in FIG. 3B, in the case of the semiconductor device 100, the p type semiconductor layer 2′ having a low dopant concentration is provided in the isolation region 100c. Holes are not injected from the p type semiconductor layer 2′.

As a result, a current flows through only a highlighted region of FIG. 3B, and a current flowing through the main region 100a and a current flowing through the sense region 100b may be separated from each other. Accordingly, as indicated by the solid line of FIG. 4, the sense ratio Im/Is may be made to be approximately constant over a broader Im range. The sense ratio in device 100 is substantially equal to a ratio of the area of the main region 100a to the area of the sense region 100b, that is, a ratio of the number of IGBT elements of the main region 100a to the number of IGBT elements of the sense region 100b.

The current dependency of the sense ratio Im/Is may be remarkably reduced by separating flows of carriers of the main and sense regions. The reason is as follows. As described above, since a current value is measured by measuring a potential difference between both ends of the sense resistor Rs, it is necessary that a potential of the emitter electrode 12 in the sense region 100b be separated from a potential of the emitter electrode 11 in the main region 100a.

Next, an example of a method of manufacturing the semiconductor device 100 of FIG. 2 will be described. On an upper side of the n⁻ type semiconductor layer 4 which is a semiconductor substrate, IGBT elements are formed using a well-known technique in the main region 100a and the sense region 100b, and the p type semiconductor layers 22 and the insulator layer 23 are formed in the isolation region 100c.

On the other hand, on a lower side of the n⁻ type semiconductor layer 4, the n type semiconductor layer 3 and the p type semiconductor layers 2 and 2′ are formed as follows.

First, n type dopant ions such as phosphorus or arsenic are injected from the lower side of the n⁻ type semiconductor layer 4. The injected n type dopant ions are activated by thermal diffusion. As a result, the n type semiconductor layer 3 is formed.

Next, a resist is provided on the isolation region 100c to mask the isolation region 100c. In this state, p type dopant ions such as boron or aluminum are injected from the lower side of the n⁻ type semiconductor layer 4 (this process will be referred to as “first p type dopant ion injection”). As a result, p type dopant ions are selectively injected to only the main region 100a and the sense region 100b. Next, the resist is removed.

A resist is provided on the main region 100a and the sense region 100b aside from the isolation region 100c to mask the main region 100a and the sense region 100b. In this state, p type dopant ions are injected from the lower side of the n⁻ type semiconductor layer 4 (this process will be referred to as “second p type dopant ion injection”). As a result, p type dopant ions are selectively injected to only the isolation region 100c.

In this case, the second p type dopant ion injection is performed with a dose amount lower than that of the first p type dopant ion injection. As a result, the p type dopant concentration in the isolation region 100c may be controlled to be lower than those in the main region 100a and the sense region 100b.

Next, the injected p type dopant ions are activated by thermal diffusion. As a result, the p type semiconductor layer 2′ is formed.

The region of the p type semiconductor layer 2′ having a low dopant concentration may slightly extend from the isolation region 100c. That is, the dopant concentration of the p⁺ type semiconductor layer 2 may also be low in portions, which are in contact with the isolation region 100c, of the main region 100a and the sense region 100b. As a result, the isolation between the main region 100a and the sense region 100b may be improved.

In this way, in the first embodiment, the dopant concentration of the p type semiconductor layer 2′ in the isolation region 100c is controlled to be lower than those of the p⁺ type semiconductor layers 2 in the main region 100a and the sense region 100b. Therefore, the current flow in the isolation region 100c may be suppressed, and the current flow from the main region 100a and the sense region 100b to the isolation region 100c may be suppressed. As a result, the sense ratio Im/Is may be made to be approximately constant, and consequently the main current Im flowing through the semiconductor device 100 may be accurately detected.

Hereinafter, several modification examples will be described.

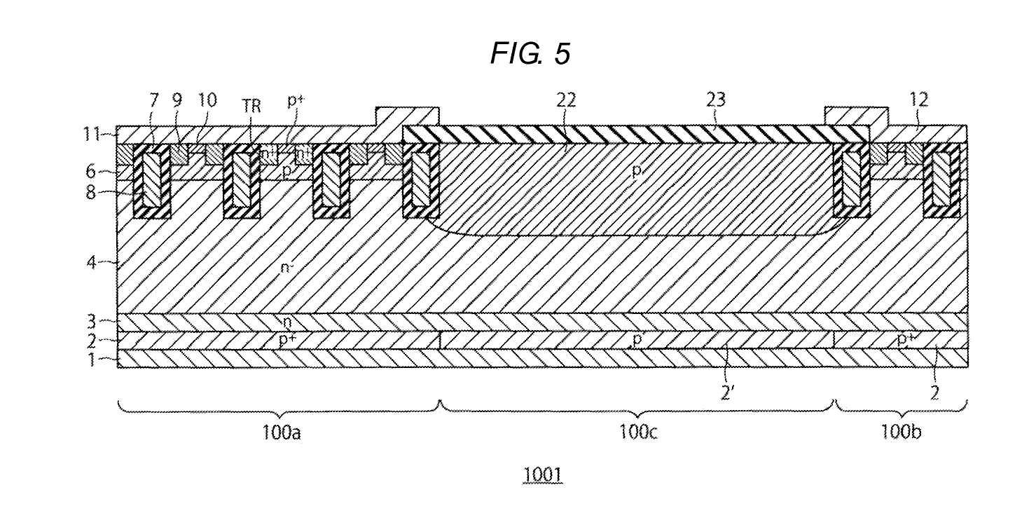

FIG. 5 is a cross-sectional view illustrating a semiconductor device 1001 which is a first modification example of the semiconductor device 100. As illustrated in FIG. 5, the p type semiconductor layer 22 may be provided across the entire isolation region 100c.

As described above, in many cases, the p type semiconductor layer 22 is provided to improve the breakdown voltage. However, in the first modification example, the p type semiconductor layer 22 on the main region 100a side is connected to the p type semiconductor layer 22 on the sense region 100b side. That is, a single p type semiconductor layer 22 spans the full width of the isolation region 100c between the final trenches TR of the main region 100a and the sense region 100b. With this configuration, there are no corners in the p type semiconductor layer 22, and thus there is no region where an electric field is concentrated. Accordingly, a decrease in breakdown voltage may be reliably suppressed with a less space of the isolation region 100c—that is, the distance between main region 100a and the sense region 100b can be reduced if desired while achieving a same or similar breakdown voltage value.

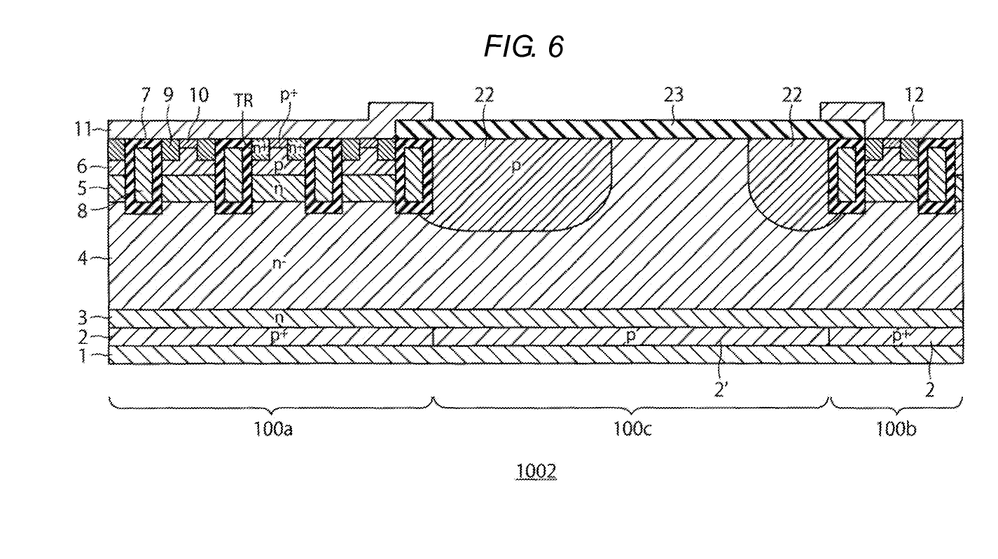

FIG. 6 is a cross-sectional view illustrating a semiconductor device 1002 which is a second modification example of the semiconductor device 100. As illustrated in FIG. 6, an n type semiconductor layer 5 may be provided as a barrier layer between the n⁻ type semiconductor layer 4 and the p type semiconductor layer 6. In the second modification example, the p type semiconductor layer 22 is divided into a portion on the main region 100a side and a portion on the sense region 100b side. As a result, an on-voltage of the IGBT may be reduced. In the IGBT of the sense region 100b, the n type semiconductor layer 5 as a barrier layer need not be provided since the reduction in on-voltage may not be important.

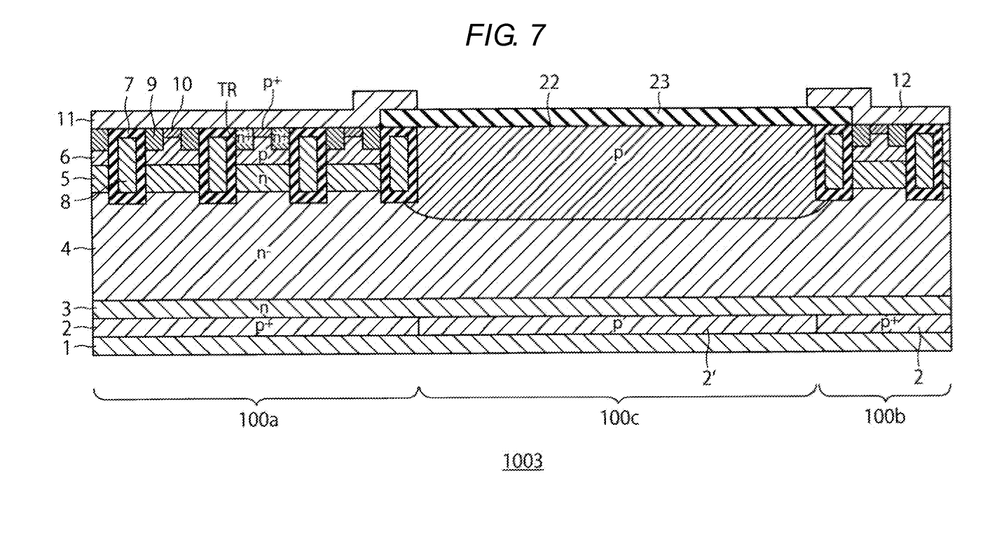

FIG. 7 is a cross-sectional view illustrating a semiconductor device 1003 which is a third modification example of the semiconductor device 100. The semiconductor device 1003 is a combination of the semiconductor device 1001 of FIG. 5 with the semiconductor device 1002 of FIG. 6. That is, the p type semiconductor layer 22 is provided across the entire isolation region 100c. Further, the n type semiconductor layer 5 is provided as a barrier layer between the n⁻ type semiconductor layer 4 and the p type semiconductor layer 6. As a result, an IGBT may be achieved in which a decrease in breakdown voltage may be reliably suppressed with a shorter space of the isolation region 100c and the amount of an on-voltage is low.

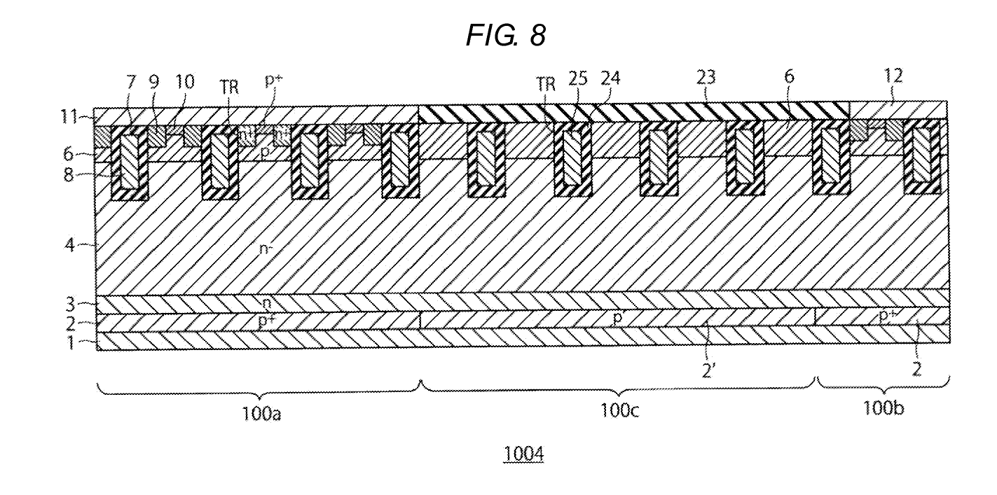

FIG. 8 is a cross-sectional view illustrating a semiconductor device 1004 which is a fourth modification example of the semiconductor device 100. In the semiconductor device 1004, the p type semiconductor layer 22 of the semiconductor device 100 of FIG. 2 is not provided in the isolation region 100c. Instead, the isolation region 100c includes the p type semiconductor layer 6 which is common to that of the main region 100a and the sense region 100b, insulating films 24 which are provided inside plural trenches TR, and emitter electrodes 25 which are provided inside the insulating films 24. The emitter electrodes 25 may be formed using the same material and the same process as those of the gate electrodes 8. The emitter electrodes 25 are electrically connected to the emitter electrode 11 of the main region 100a through an interconnect (not specifically illustrated).

As illustrated in FIG. 8, by providing the trenches TR in the isolation region 100c, the breakdown voltage between the gate electrodes 8 and the collector electrode 1 may be improved. In addition, since the thick p type semiconductor layer 22 is not included, which is unlike the semiconductor device 100 of FIG. 2, the manufacturing process may be simplified.

Structures of the trenches TR and the emitter electrodes 25 of FIG. 8 may be combined with the semiconductor device 1002 of FIG. 6.

### Second Embodiment

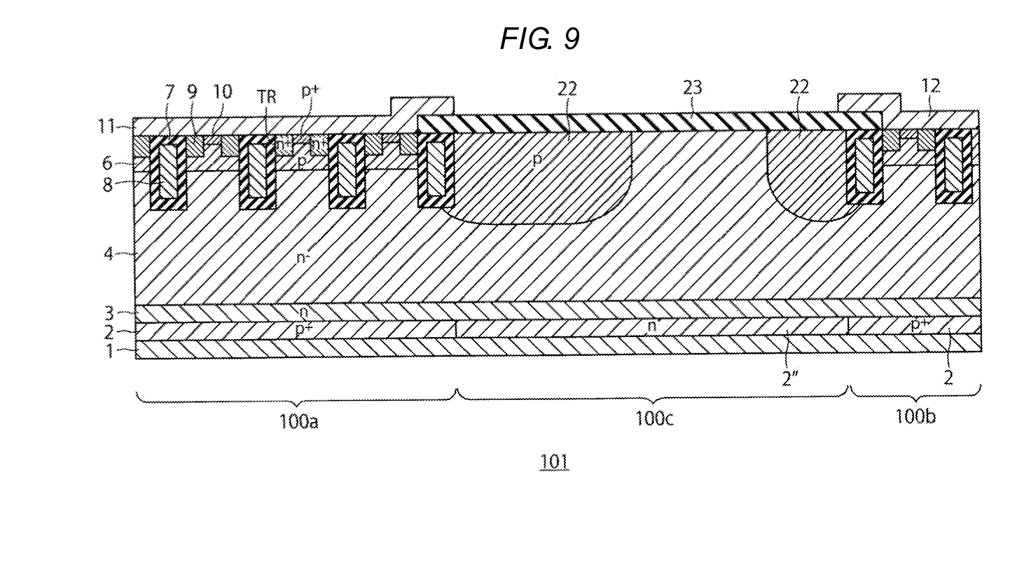

FIG. 9 is a cross-sectional view illustrating a semiconductor device 101 according to a second embodiment. The same or substantially similar components as those depicted in FIG. 2 are represented by the same reference numerals. In the following description, differences from those of FIG. 2 will be mainly described.

Semiconductor layers 2 and 2″, which are collector layers, are provided on the collector electrode 1. In this embodiment, the conductivity type of the semiconductor layer 2 in the main region 100a and the sense region 100b is the p⁺ type. On the other hand, the conductivity type of the semiconductor layer 2″ in the isolation region 100c is the n type.

Therefore, holes are not injected from the semiconductor layer 2″ in the isolation region 100c. As a result, similarly to the first embodiment, the current flow from the main region 100a and the sense region 100b to the isolation region 100c may be further suppressed.

For example, the semiconductor layers 2 and 2″ in the semiconductor device 101 are formed as follows.

A resist is provided on the isolation region 100c to mask the isolation region 100c. In this state, p type dopant ions are injected from the lower side of the n⁻ type semiconductor layer 4. As a result, p type dopant ions are selectively injected to only the main region 100a and the sense region 100b. Next, the resist is removed.

A resist is provided on the main region 100a and the sense region 100b and not on the isolation region 100c to mask the main region 100a and the sense region 100b. In this state, n type dopant ions are injected from the lower side of the n⁻ type semiconductor layer 4. As a result, n type dopant ions are selectively injected to only the isolation region 100c.

Next, the injected n type and p type dopant ions are activated by thermal diffusion. As a result, the semiconductor layers 2 and 2″ are formed.

The n⁻ type semiconductor layer 4 may also be used as the semiconductor layer 2″ without injecting n type dopant ions.

In the second embodiment, the conductivity type of the semiconductor layer 2″ in the isolation region 100c is the n type. Therefore, the current flow in the isolation region 100c may be further suppressed compared to the first embodiment, and the current flow from the main region 100a and the sense region 100b to the isolation region 100c may be suppressed. Accordingly, compared to the first embodiment, the main current Im flowing through the semiconductor device 101 may be more accurately detected/determined.

### Third Embodiment

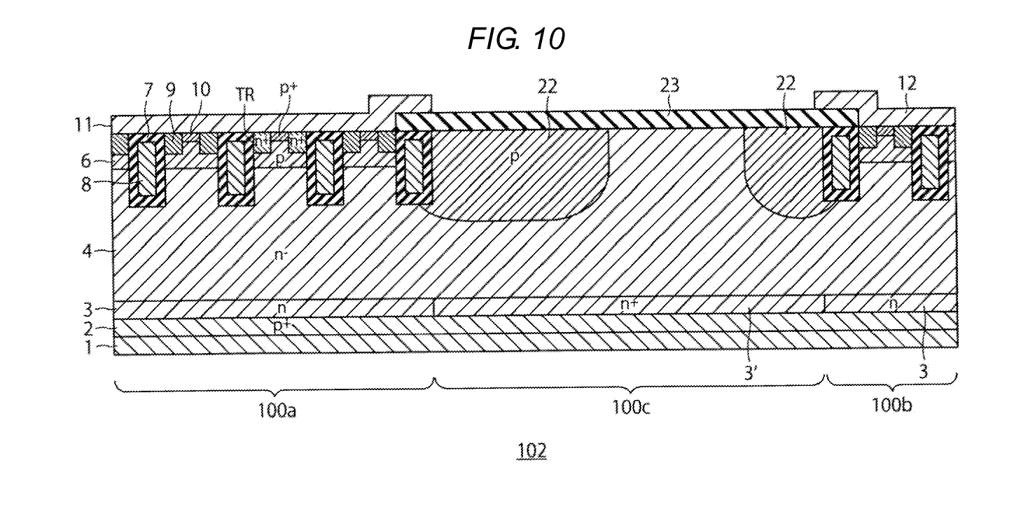

FIG. 10 is a cross-sectional view illustrating a semiconductor device 102 according to a third embodiment. The same components as those of FIG. 2 are represented by the same reference numerals. In the following description, different points from those of FIG. 2 will be mainly described. In the semiconductor device 102, the dopant concentration of the p⁺ type semiconductor layer 2 may be the same as those of the main region 100a, the sense region 100b, and the isolation region 100c.

In this third embodiment, in the main region 100a and the sense region 100b, n type semiconductor layers 3 may be provided between the p⁺ type semiconductor layer 2 and the n⁻ type semiconductor layer 4. On the other hand, in the isolation region 100c, an n⁺ type semiconductor layer 3′ is provided between the p⁺ type semiconductor layer 2 and the n⁻ type semiconductor layer 4.

The dopant concentration of the n⁺ type semiconductor layer 3′ in the isolation region 100c is higher than that those of the n type semiconductor layers 3 in the main region 100a and the sense region 100b. Specifically, the maximum value of the dopant concentration of the n⁺ type semiconductor layer 3′ in the isolation region 100c is approximately 10¹⁸/cm³. On the other hand, the maximum value of the dopant concentrations of the n type semiconductor layers 3 in the main region 100a and the sense region 100b is approximately 10¹⁷/cm³ or less. The dopant concentration of the n type semiconductor layer 3 in the main region 100a may be different from that of the n type semiconductor layer 3 in the sense region 100b.

Since the dopant concentration of the n⁺ type semiconductor layer 3′ in the isolation region 100c is high, the amount of holes injected from the p⁺ type semiconductor layer 2 to the n⁻ type semiconductor layer 4 in the isolation region 100c is suppressed. As a result, the current flow from the main region 100a and the sense region 100b to the isolation region 100c may be reduced.

For example, the n⁺ type semiconductor layer 3′ in the semiconductor device 102 is formed as follows.

A resist is provided on the isolation region 100c to mask the isolation region 100c. In this state, n type dopant ions are injected from the lower side of the n⁻ type semiconductor layer 4 (this process will be referred to as “first n type dopant ion injection”). As a result, n type dopant ions are selectively injected to only the main region 100a and the sense region 100b. Next, the resist is removed.

A resist is provided on the main region 100a and the sense region 100b aside from the isolation region 100c to mask the main region 100a and the sense region 100b. In this state, n type dopant ions are injected from the lower side of the n⁻ type semiconductor layer 4 (this process will be referred to as “second n type dopant ion injection”). As a result, n type dopant ions are selectively injected to only the isolation region 100c.

In this case, the second n type dopant ion injection is performed with a dose amount higher than that of the first n type dopant ion injection. As a result, the n type dopant concentration in the isolation region 100c may be controlled to be higher than those in the main region 100a and the sense region 100b.

Next, the injected n type dopant ions are activated by thermal diffusion. As a result, the n type semiconductor layers 3 and 3′ are formed.

In this way, in the third embodiment, the dopant concentration of the n⁺ type semiconductor layer 3′ in the isolation region 100c is controlled to be higher than those of the n type semiconductor layers 3 in the main region 100a and the sense region 100b. Therefore, the current flow to the isolation region 100c may be suppressed, and the current flow from the main region 100a and the sense region 100b to the isolation region 100c may be suppressed. As a result, similarly to the first embodiment, the main current Im flowing through the semiconductor device 102 may be accurately detected/determined.

### Fourth Embodiment

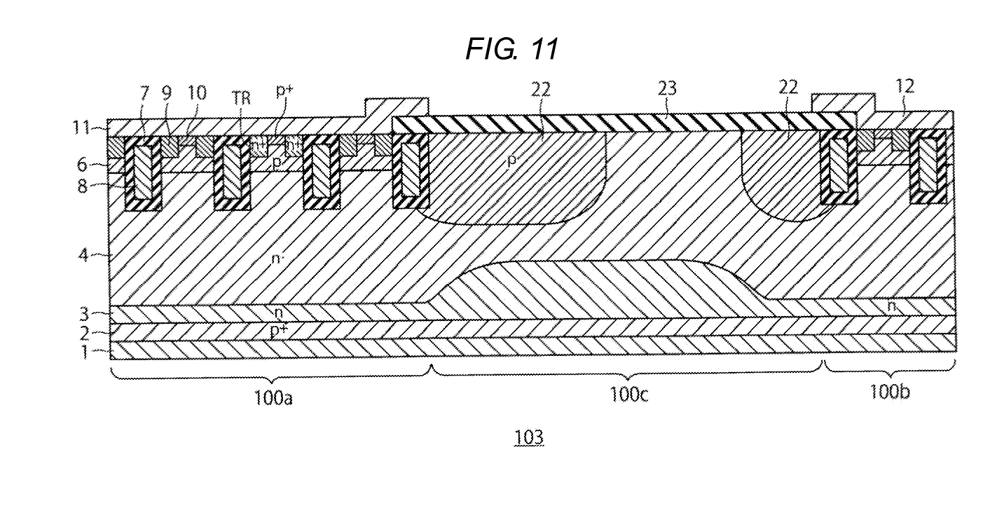

FIG. 11 is a cross-sectional view of a semiconductor device 103 according to a fourth embodiment. The same or substantially similar components as those depicted in FIG. 5 are represented by the same reference numerals. In the following description, different points from those of FIG. 5 will be mainly described. In the semiconductor device 103, the dopant concentration of the n type semiconductor layer 3 may be the same in the main region 100a, the sense region 100b, and the isolation region 100c.

In this fourth embodiment, the thickness of the n type semiconductor layer 3 in the isolation region 100c is greater than that of the n type semiconductor layer 3 in the main region 100a and the sense region 100b. Specifically, the thickness of the n type semiconductor layer 3 in the isolation region 100c is approximately 5 μm. On the other hand, the thickness of the n type semiconductor layer 3 in the main region 100a and the sense region 100b is approximately 1 μm. The thickness of the n type semiconductor layer 3 in the main region 100a may be different from that of the n type semiconductor layer 3 in the sense region 100b.

Since the n type semiconductor layer 3 in the isolation region 100c is thick, the amount of holes injected from the p⁺ type semiconductor layer 2 to the n⁻ type semiconductor layer 4 in the isolation region 100c is suppressed. As a result, the current flow from the main region 100a and the sense region 100b to the isolation region 100c may be minimized.

For example, the n type semiconductor layer 3 in the semiconductor device 103 is formed as follows.

First, n type dopant ions are injected from the lower side of the n⁻ type semiconductor layer 4 to the entire surface (this process will be referred to as “first n type dopant ion injection”).

A resist is provided on the main region 100a and the sense region 100b aside from the isolation region 100c to mask the main region 100a and the sense region 100b. In this state, n type dopant ions are injected from the lower side of the n⁻ type semiconductor layer 4 (this process will be referred to as “second n type dopant ion injection”). As a result, n type dopant ions are selectively injected to only the isolation region 100c.

In this case, the second n type dopant ion injection is performed with an energy higher than that of the first n type dopant ion injection. As a result, n type dopant ions may be injected to a deeper region of the n⁻ type semiconductor layer 4.

Next, the injected n type dopant ions are activated by thermal diffusion. As a result, the n type semiconductor layer 3 is formed as depicted in FIG. 11.

In this way, in the fourth embodiment, the n type semiconductor layer 3 in the isolation region 100c is formed thick. Therefore, the current flow to the isolation region 100c may be suppressed, and the current flow from the main region 100a and the sense region 100b to the isolation region 100c may be suppressed. As a result, similarly to the third embodiment, the main current Im flowing through the semiconductor device 103 may be accurately detected/determined.

In the above-described semiconductor devices 101 to 103, the same modification examples of FIGS. 5 to 8 may be considered. In addition, two or more of the first to fourth embodiments may be combined. Further, in the examples of the first to fourth embodiments, the first conductivity type is the p type, and the second conductivity type is the n type. However, conversely, the first conductivity type may be the n type, and the second conductivity type may be the p type. In addition, the respective semiconductor layers may be formed by injecting ions to the semiconductor substrate or by depositing a semiconductor film on the semiconductor substrate.

In a so-called reverse conducting (RC)-IGBT, a technique of separating an IGBT region and a diode region from each other during the operation of a diode is known.

However, such a RC-IGBT is completely different from the semiconductor devices 100 to 103 described in the first to fourth embodiments. When the main region 100a and the sense region 100b are simultaneously operated, the semiconductor devices 100 to 103 have a structure for making the main current and the sense current not interfere with each other rather than having the separated regions interact with each other.

More specifically, in the semiconductor device 100 according to the first embodiment, the dopant concentration of the p type semiconductor layer 2′ in the isolation region 100c is controlled to be low. In the semiconductor device 101 according to the second embodiment, the conductivity type of the semiconductor layer 2″ in the isolation region 100c is not the p type but the n type. In the semiconductor device 102 according to the third embodiment, the dopant concentration of the n⁺ type semiconductor layer 3′ in the isolation region 100c is controlled to be high. In the semiconductor device 103 according to the fourth embodiment, the n type semiconductor layer 3 in the isolation region 100c is formed thick.

Further, in the semiconductor devices 100 to 103 described in the respective embodiments, the emitter electrode 11 in the main region 100a is separated from the emitter electrode 12 in the sense region 100b. Accordingly, the emitter electrode 11 and the emitter electrode 12 may have different potentials. On the other hand, in the RC-IGBT, the potential of an emitter electrode in the IGBT region is the same as that of an anode electrode in the diode region. In the example embodiments, if the emitter electrode 12 of the sense IGBT and the emitter electrode 11 of the main IGBT are controlled to have the same potential, there is no potential difference across the sense resistor Rs, as clearly seen from the equivalent circuit diagram illustrated in FIG. 1, and thus the current value through the main IGBT region cannot be detected. Further, it may be preferable that current flows in an IGBT region and an FWD (free wheeling diode) region be separated from each other in order to improve respective characteristics thereof. However, a current does not flow through the IGBT region and the FWD region at the same time. In addition, unlike the RC-IGBT, an area ratio Sm/Ss of the main region 100a to the sense region 100b is substantially equivalent to the sense ratio Im/Is. In addition, typically, the area Sm of the sense region 100b is relatively small, such as 1/100 or less of the area Ss of the main region 100a.

In this way, the RC-IGBT in which the IGBT region is separated from the diode region has a structure and an object different from those of the semiconductor devices 100 to 103 described in the respective embodiments of this disclosure. Accordingly, the technique of separating the IGBT region and the diode region in the RC-IGBT is not the same as the technique for separating the main region 100a and the sense region 100b in the example embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An insulated gate bipolar transistor, comprising:
a main region and a sense region spaced from the main region; and
a first semiconductor layer between the main region and the sense region, the first semiconductor layer being in contact with a first portion of a collector layer of a first conductivity type in the main region and a second portion of the collector layer in the sense region, the first semiconductor layer being one selected from a layer of the first conductivity type with a first conductivity type dopant concentration that is lower than a first conductivity type dopant concentration of the collector layer or a layer of a second conductivity type that is opposite the first conductivity type.

2. The insulated gate bipolar transistor according to claim 1, further comprising:
a buffer layer of the second conductivity type on the semiconductor layer and each of the first and second portions of the collector layer;
a first base layer of the second conductivity type on the buffer layer;
a second base layer on the first conductivity type on the first base layer in the main and sense regions; and
a plurality of gate electrodes adjacent the first and second base layers via a gate insulating film.

3. The insulated gate bipolar transistor according to claim 2, further comprising:
a semiconductor region of the first conductivity type in the first base layer between the main and sense regions, the semiconductor region having a first portion adjacent to a gate electrode in the main region and a second portion adjacent to a gate electrode in the sense region, the first and second portion of the semiconductor region being spaced from each other by a portion of the first base layer.

4. The insulated gate bipolar transistor according to claim 3, wherein the plurality of gate electrodes extend into the first base layer to a first distance and the semiconductor region extends into the first base layer a second distance that is greater than the first distance.

5. The insulated gate bipolar transistor according to claim 2, further comprising:
a semiconductor region of the first conductivity type in the first base layer between the main and sense regions, the semiconductor region being adjacent to a gate electrode in the main region and a gate electrode in the sense region.

6. The insulated gate bipolar transistor according to claim 5, wherein the plurality of gate electrodes extend into the first base layer to a first distance and the semiconductor region extends into the first base layer a second distance that is greater than the first distance.

7. The insulated gate bipolar transistor according to claim 2, wherein the plurality of gate electrodes includes gate electrodes between the main and sense regions.

8. The insulated gate bipolar transistor according to claim 2, further comprising:
an insulating film on the first base layer between the main and sense regions.

9. The insulated gate bipolar transistor according to claim 2, wherein the buffer layer has a thickness in the sense region that is greater than a thickness in the main and sense regions.

10. A semiconductor device having a first region, a second region spaced from the first region, and a third region between the first region and the second region, the device comprising:
a first electrode;
a first semiconductor layer on the first electrode, the first semiconductor layer having a first conductivity type in the first and second regions and, in the third region, having one of a first conductivity type dopant concentration lower than a first conductivity type dopant concentration in the first and second regions or a second conductivity type that is opposite the first conductivity type;
a second semiconductor layer of the second conductivity type on the first semiconductor layer;
a plurality of gate electrodes on the second semiconductor layer via a gate insulating film;
a third semiconductor layer of the second conductivity type on the second semiconductor layer and between adjacent gate electrodes in the first and second regions; and
a fourth semiconductor layer of the first conductivity type on the third semiconductor layer in the third region and contacting the gate insulating film of a gate electrode in the first region and the gate insulating film of a gate electrode in the second region.

11. The semiconductor device according to claim 10, further comprising:
an insulator layer on the fourth semiconductor layer in the third region.

12. The semiconductor device according to claim 10, wherein the fourth semiconductor layer is provided in a first portion adjacent to the first region and a second portion adjacent to the second region, and a portion of the third semiconductor layer is between the first and second portions of the fourth semiconductor layer.

13. The semiconductor device according to claim 10, wherein the fourth semiconductor layer is provided in a single portion spanning the third region between the first and second regions.

14. The semiconductor device according to claim 10, wherein the first semiconductor layer has the second conductivity type in the third region.

15. The semiconductor device according to claim 10, wherein the first semiconductor layer in the third region has the first conductivity type dopant concentration that is lower than the first conductivity type dopant concentration of the first semiconductor layer in the first and second regions.

16. A semiconductor device having a first region, a second region spaced from the first region, and a third region between the first region and the second region, the device comprising:
a first electrode;
a first semiconductor layer of a first conductivity type on the first electrode;
a second semiconductor layer of a second conductivity type that is opposite the first conductivity type on the first semiconductor layer, the second semiconductor layer in the third region having one of a dopant concentration that is higher than a dopant concentration of the second semiconductor layer in the first and second regions or a thickness that is greater than a thickness of the second semiconductor layer in the first and second regions;
a third semiconductor layer of the second conductivity type on the second semiconductor layer;
a plurality of gate electrodes on the third semiconductor layer via a gate insulating film;
a fourth semiconductor layer of the first conductivity type on the third semiconductor layer and between adjacent gate electrodes in the first and second regions; and
a fifth semiconductor layer of the second conductivity type in the third region and contacting the gate insulating film of a gate electrode in the first region and the gate insulating film of a gate electrode in the second region.

17. The semiconductor device according to claim 16, further comprising:
an insulator layer that is provided on the third semiconductor layer in the third region.

18. The semiconductor device according to claim 16, wherein the fifth semiconductor layer is provided in a first portion and a second portion, and a portion of the third semiconductor layer is between the first and second portions of the fifth semiconductor layer.

19. The semiconductor device according to claim 16, wherein the second semiconductor layer in third region has the dopant concentration that is higher than the dopant concentration of the second semiconductor layer in the first and second regions.

20. The semiconductor device according to claim 16, wherein the second semiconductor layer in the third region has the thickness that is greater than the thickness of the second semiconductor layer in the first and second regions.
